(19) United States
(12) Patent Application Publication
(10) Pub. No.: US 2023/0366119 A1
(43) Pub. Date: Nov. 16, 2023

(54) PREPLATING EDGE DRY

(71) Applicant: LAM RESEARCH CORPORATION, Fremont, CA (US)

(72) Inventors: Kari THORKELSSON, Portland, OR (US); Stephen J. BANIK, Philadelphia, PA (US); Bryan BUCKALEW, Tualatin, OR (US)

(21) Appl. No.: 18/028,638

(22) PCT Filed: Sep. 29, 2021
(86) PCT No.: PCT/US2021/052498

§ 371 Date: Mar. 27, 2023

Related U.S. Application Data
(60) Provisional application No. 63/086,507, filed on Oct. 1, 2020.

(51) Int. Cl. C25D 21/08; C25D 7/12

(52) U.S. Cl. CPC C25D 21/08; C25D 7/123

(57) ABSTRACT

A chamber in a substrate processing system comprises a substrate holder configured to support a substrate, a nozzle arranged above the substrate, the nozzle configured to inject a pre-wetting liquid onto a surface of the substrate during a pre-wetting period, and at least one gas injector arranged radially outward of the nozzle. The at least one gas injector is configured to inject gas toward an edge of the substrate for a drying period subsequent to the pre-wetting period to remove the pre-wetting liquid from the edge of the substrate.

### CROSS-REFERENCE TO RELATED APPLICATIONS

This application claims the benefit of U.S. Provisional Application No. 63/086,507, filed on Oct. 1, 2020. The entire disclosure of the application referenced above is incorporated herein by reference.

### FIELD

The present disclosure relates to substrate processing systems, and more particularly to electrodeposition on an edge of a substrate.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may comprise one or more processing chambers configured to perform an electroplating process (e.g., electrodeposition) on a substrate. For example, an electrodeposition process may comprise through-resist, through-mask, and/or photoresist patterned electrodeposition. Electrodeposition processes comprise applying a liquid to pre-wet a surface of the substrate (e.g., a conductive base or seed layer on a surface of the substrate). The liquid is applied to the surface of the substrate in a pre-wetting process chamber. A plating solution is then applied to the wet surface (e.g., in an electrodeposition chamber).

### SUMMARY

A chamber in a substrate processing system comprises a substrate holder configured to support a substrate, a nozzle arranged above the substrate, the nozzle configured to inject a pre-wetting liquid onto a surface of the substrate during a pre-wetting period, and at least one gas injector arranged radially outward of the nozzle. The at least one gas injector is configured to inject gas toward an edge of the substrate for a drying period subsequent to the pre-wetting period to remove the pre-wetting liquid from the edge of the substrate.

In other features, the at least one gas injector is arranged to inject the gas to remove the pre-wetting liquid from the edge of the substrate without removing the pre-wetting liquid from an interior of the substrate. The at least one gas injector is arranged to inject the gas away from an interior of the substrate and radially outward toward the edge of the substrate. The at least one gas injector is arranged to inject the gas at an acute angle relative to the surface of the substrate holder. The at least one gas injector comprises two or more gas injectors that are azimuthally spaced apart. The substrate holder is configured to rotate during at least one of the pre-wetting period and the drying period. The at least one gas injector is mounted on an assembly that is configured to rotate during the drying period.

In other features, the at least one gas injector is configured to move between a first position and a second position. The at least one gas injector is moved to the first position during the pre-wetting period and during transport of the substrate to and from the substrate holder and moved to the second position during the drying period. A system comprises the chamber and further comprises a controller configured to control the at least one gas injector to inject the gas during the drying period. The at least one gas injector is arranged to inject the gas radially inward from an edge of the substrate toward an interior of the substrate.

A method of operating a chamber configured to implement a pre-wetting process in a substrate processing system comprises arranging a substrate on a substrate holder, using a nozzle arranged above the substrate, injecting a pre-wetting liquid onto a surface of the substrate during a pre-wetting period, and, using at least one gas injector arranged radially outward of the nozzle, injecting gas toward an edge of the substrate for a drying period subsequent to the pre-wetting period to remove the pre-wetting liquid from the edge of the substrate.

In other features, injecting the gas comprises injecting the gas to remove the pre-wetting liquid from the edge of the substrate without removing the pre-wetting liquid from an interior of the substrate. Injecting the gas comprises injecting the gas away from an interior of the substrate and radially outward toward the edge of the substrate. Injecting the gas comprises injecting the gas at an acute angle relative to the surface of the substrate holder. Injecting the gas comprises injecting the gas using two or more gas injectors that are azimuthally spaced apart.

The method further comprises rotating the substrate holder during at least one of the pre-wetting period and the drying period. The method further comprises rotating an assembly comprising the at least one gas injector during the drying period. The method further comprises moving the at least one gas injector between a first position and a second position. The method further comprises moving the at least one gas injector to the first position during the pre-wetting period and during transport of the substrate to and from the substrate holder and moving the at least one gas injector to the second position during the drying period. The method further comprises using a controller to control the at least one gas injector to inject the gas during the drying period. Injecting the gas includes injecting the gas radially inward from an edge of the substrate toward an interior of the substrate

A chamber in a substrate processing system comprises a substrate holder configured to support a substrate, a nozzle arranged above the substrate that is configured to inject a pre-wetting liquid onto a surface of the substrate during a pre-wetting period, and at least one drying pad arranged around an edge of the substrate. The at least one drying pad is configured to contact the edge of the substrate for a drying period subsequent to the pre-wetting period to remove the pre-wetting liquid from the edge of the substrate.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A shows an example substrate processing tool configured to perform electrodeposition according to the present disclosure;

FIG. 1B shows an example electrodeposition assembly of the substrate processing tool of FIG. 1A;

FIG. 1C is an image of an example substrate that was dry prior to electroplating;

FIG. 1D is an image of an example substrate that was wet prior to electroplating;

FIGS. 2A and 2B show an example pre-wetting chamber configured to apply a pre-wetting liquid to a surface of a substrate and to dry an edge of the substrate according to the present disclosure;

FIGS. 3A and 3B show an example substrate prior to and subsequent to a predetermined drying period according to the present disclosure;

FIGS. 4A and 4B show another example substrate prior to and subsequent to a predetermined drying period according to the present disclosure;

FIG. 5 illustrate steps of an example method for drying an edge of a substrate according to the present disclosure; and

FIG. 6 is an example computing system configured to implement a controller that executes the method of FIG. 5 according to the present disclosure.

In the drawings, reference numbers may be reused to identify similar and/or identical elements.

### DETAILED DESCRIPTION

During electrodeposition, a substrate comprising a conductive base or seed layer is exposed to a conductive plating solution in an electrodeposition chamber. In some examples, the plating solution is acidic. Electrical contact is established with a contact region of the substrate. For example, the contact region corresponds to an outer edge of the substrate. Current is transmitted through the substrate via the contact region to facilitate plating of the substrate using the plating solution.

If electrical contacts are exposed to the plating solution, electrodeposition may preferentially occur on the contracts and the contact region relative to an interior region of the substrate. Accordingly, a compressible seal (e.g., a “lip seal”) may be provided near the outer edge of the substrate to seal the contact region from the plating solution. If any of the plating solution is present in the sealed contact region, a voltage difference between the seed layer and the contact region may cause corrosion of the seed layer and deposition of the plating onto the contacts and/or the contact region. Further, if the plating solution is acidic, the seed layer may be chemically etched. Corrosion or etching of the seed layer and deposition of the plating onto the contact and/or contact region causes variations in a difference between resistances of the contacts and respective portions of the substrate. These variations cause non-uniformity in the electrodeposition of the plating.

In some examples, the substrate is mounted into an assembly such as a substrate holder that contains the seal and other components, such as electrical contacts arranged to engage the contact region. This assembly is transported through stations (i.e., chambers) of a substrate processing tool, such as respective stations configured to perform pretreatment and/or pre-wetting, electrodeposition, rinsing, etc. Transporting the entire assembly between chambers increases complexity and power requirements. In other examples, the substrate is transported between chambers and mounted within respective substrate holders of each of the chambers. In these examples, the effectiveness of the seal may be compromised by repeated transportation of the substrate into and out of the respective chambers, which may allow pre-wetting liquid (e.g., water) on the surface of the substrate to leak into the contact region. The plating solution may diffuse through the pre-wetting liquid into the contact region. Example pre-wetting chambers are described in more detail in U.S. Pat. No. 10,301,738, issued on May 28, 2019, the entire disclosure of which is incorporated herein. An example substrate holder and seal assembly for performing electrodeposition on a substrate is described in more detail in U.S. Pat. No. 10,364,505, issued on Jul. 30, 2019, the entire disclosure of which is incorporated herein.

Pre-wetting and electrodeposition systems and methods according to the present disclosure are configured to dry the contact region (i.e., an edge) of the substrate subsequent to applying the pre-wetting liquid and prior to sealing the contact region and applying the plating solution. Drying the contract region improves the effectiveness of the seal and prevents the plating solution from diffusing into liquid within the sealed contact region subsequent to applying the seal. Accordingly, corrosion of the seed layer in the contact region is reduced.

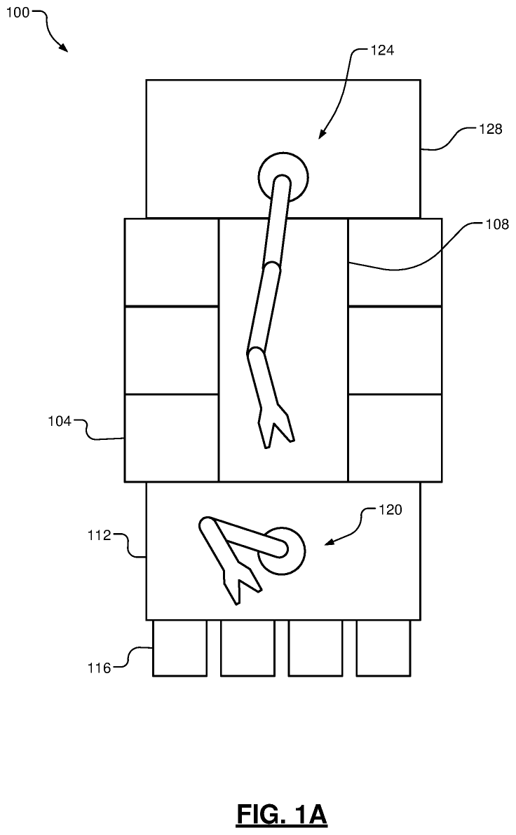

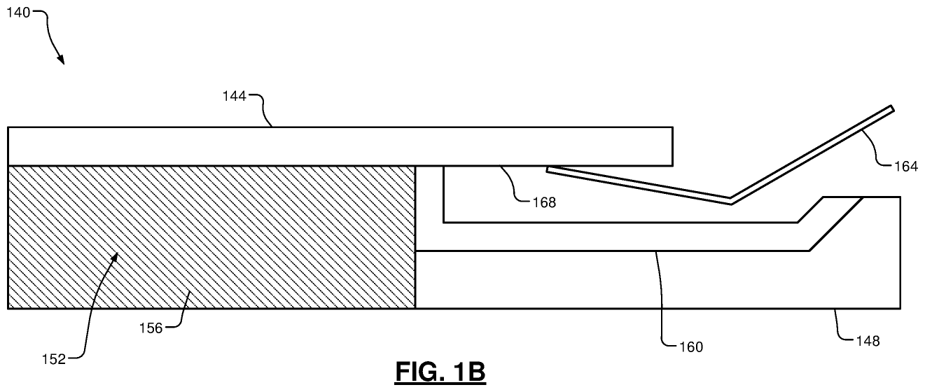

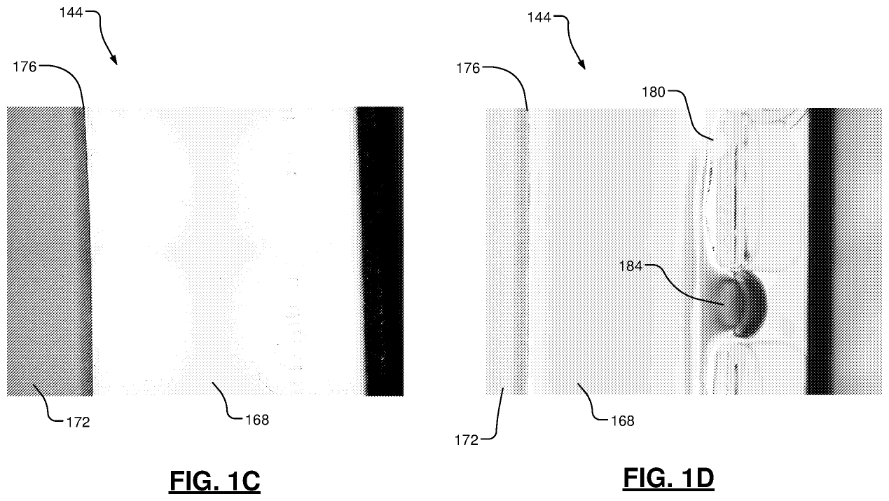

FIG. 1A shows an example substrate processing tool 100 configured to perform electrodeposition according to the present disclosure. The substrate processing tool 100 comprises a plurality of processing stations (i.e., chambers) 104 each configured to perform a respective process on a substrate. For example, at least one of the processing stations 104 (e.g., an electrodeposition chamber) is configured to perform electrodeposition on the substrate and at least one of the processing stations 104 (e.g., a pre-wetting chamber) is configured to apply a pre-wetting liquid to a surface of the substrate. In an embodiment, the one of the processing stations 104 configured to apply the pre-wetting liquid is further configured to perform a drying process to dry an edge of the substrate prior to transporting the substrate to another one of the processing stations 104 for electrodeposition. In another embodiment, the pre-wetting of the substrate and the drying process are performed in different ones of the processing stations 104.

As shown, the substrate processing tool 100 comprises a transfer volume 108, an equipment front end module 112, and one or more loading stations 116. Substrates are loaded into the substrate processing tool 100 via one of the loading stations 116. Robot 120 transfers the substrates from the loading stations 116, through the equipment front end module 112 and the transfer volume 108 into one of the processing stations 104 (e.g., a pre-treatment processing station). A robot 124 of a back end module 128 transfers the substrates between the processing stations 104.

Referring now to FIG. 1B, at least one of the processing stations 104 may be an electrodeposition chamber that comprises an electrodeposition assembly 140. The electrodeposition assembly 140 is configured to perform electrodeposition on a substrate 144. The substrate holder 148 defines an interior volume 152. The interior volume 152 is configured to contain an electroplating solution 156 (e.g., a copper electroplating solution). The substrate holder 148 is configured to support the substrate 144 above the volume 152 in contact with the electroplating solution 156. For example, a seal (e.g., a lip seal) 160 is disposed on the substrate holder 148. The substrate 144 is supported on the seal 160. The seal 160 seals against a surface of the substrate 144 to retain the electroplating solution 156 within the volume 152.

One or more contacts (e.g., metallic, conductive contacts) 164 are arranged to contact a surface region 168 (e.g., a contact area) of the substrate 144 radially outside of the electroplating solution 156 and the seal 160. The seal 160 prevents the electroplating solution 156 from reaching the surface region 168 to prevent electrodeposition in the surface region 168.

In some examples, the surface region 168 may be wet prior to arranging the substrate 144 in the electrodeposition assembly 140. Liquid on the surface region 168 and/or between the seal 160 and the substrate 144 may interfere the effectiveness of the seal 160. Accordingly, the electroplating solution 156 may seep or diffuse past the seal 160 onto the surface region 168. The electroplating solution 156 may cause the liquid on the surface region 168 to become acidic, which may cause seed corrosion on the surface region 168. The electroplating solution 156 may cause the liquid on the surface region 168 to become conductive, which may cause corrosion of the seed on the surface region 168 and corresponding plating on the contacts 164.

FIG. 1C is an image of an example of the substrate 144 that was dry prior to electroplating. Copper plating 172 is formed on the substrate 144 in a region exposed to the electroplating solution 156 within the seal 160. A location of the seal 160 is indicated at 176. Conversely, the copper plating 172 is not formed on the surface region 168 outside of the seal 160. Further, the surface region 168 is free of corrosion or other damage.

FIG. 1D is an image of an example of the substrate 144 that was wetted prior to electroplating. In this example, copper plating 172 is formed on the substrate 144 in the region exposed to the electroplating solution 156 within the seal 160. However, corrosion 180 is present on the surface region 168 outside of the seal 160. Further, severe corrosion 184 is present on the surface region 168. In other words, pre-wetting the substrate 144 facilitated leaking or diffusion of the electroplating solution 156 onto the surface region 168, which caused unwanted corrosion of the surface region 168.

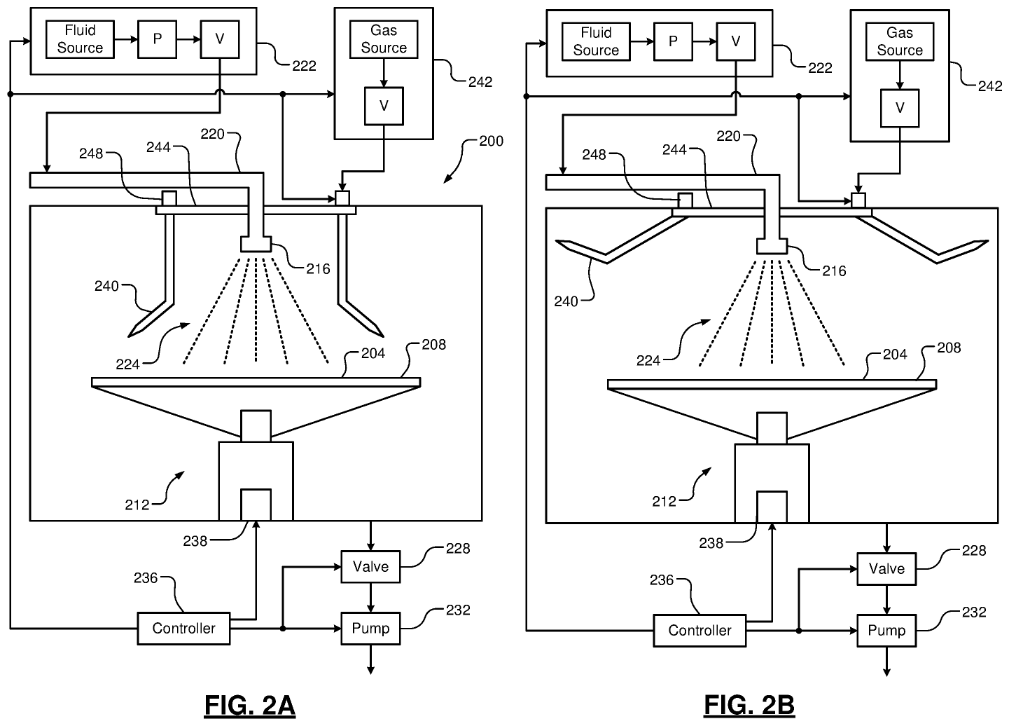

Referring now to FIGS. 2A and 2B, an example pre-wetting chamber 200 according to the present disclosure is configured to apply a pre-wetting liquid to a surface (e.g., a conductive seed layer, such as copper) of a substrate 204 and to dry an edge 208 of the substrate 204. The pre-wetting chamber 200 comprises a substrate holder (e.g., a pedestal or chuck) 212 configured to support the substrate 204.

The chamber 200 comprises one or more nozzles 216 in fluid communication with a manifold or conduit 220. The conduit 220 is arranged to supply the pre-wetting liquid (e.g., from a fluid delivery system 222 comprising a fluid source, pump (P), and valve (V)) to the chamber 200 via the nozzle 216 during a pre-wetting period. In some embodiments, the nozzle 216 is configured to inject the pre-wetting liquid in a fan or conical spray pattern 224 to distribute the pre-wetting liquid across the surface of the substrate 204. The chamber 200 may be pumped down (e.g., to vacuum) using a valve 228 and pump 232 (e.g., in response to control signals provided by a controller 236) prior to injecting the pre-wetting liquid. In some embodiments, the substrate holder 212 is configured to rotate, which correspondingly rotates the substrate 204, during and/or subsequent to application of the pre-wetting liquid. Rotating the substrate 204 facilitates distribution of the pre-wetting liquid on the surface of the substrate 204. For example, the chamber 200 comprises an actuator or motor 238 responsive to the controller 236 and configured to rotate the substrate holder 212.

The chamber 200 comprises one or more gas injectors (e.g., jets or nozzles) 240 positioned to dry the edge 208 of the substrate 204. For example, the gas is supplied to the gas injectors 240 using a gas delivery system 242 (e.g., comprising a gas source and valve (V)). The gas injectors 240 are positioned radially outward of the nozzle 216 and are arranged to inject air or another gas (e.g., an inert gas, nitrogen, argon, etc.) at an acute angle relative to the surface of the substrate 204. For example, the gas injectors 240 are arranged to inject air at an angle of 10-80 degrees relative to the surface of the substrate 204. The gas injectors 240 inject the gas away from an interior and toward the edge 208 of the substrate 204 to dry the edge 208. Although two of the gas injectors 240 are shown, fewer (e.g., only one) or more (e.g., three or more) of the gas injectors 240 may be provided. For example, two or more of the gas injectors 240 may be uniformly azimuthally spaced above the substrate 204.

Although as shown the gas injectors 240 are arranged to inject the gas radially outward relative to the substrate 204, in another embodiment gas may be injected radially inward from an outer perimeter of the substrate 204. In this embodiment, the injected gas forces liquid away from the edge 208 to the interior of the substrate 204. In this manner, the edge 208 of the substrate 204 is dried while the interior of the substrate 204 remains wet.

The gas injectors 240 inject the gas continuously or in a pulsed manner for a predetermined drying period (e.g., 1-10 seconds, in response to commands from the controller 236). The predetermined drying period is selected to allow sufficient time for the edge 208 to be dried without allowing the interior of the surface of the substrate 204 to dry prior to transporting the substrate 204 to an electrodeposition chamber. The substrate holder 212 may be rotated to rotate the substrate 204 during the drying period. Alternatively, in other embodiments, the gas injectors 240 may be mounted on an assembly 248 configured to rotate relative to the substrate 204. In some examples, the injected gas may be heated prior to the drying period to facilitate drying of the edge 208.

In an embodiment, the gas injectors 240 may be configured to be raised and lowered (e.g., using actuators 248 responsive to the controller 236). The gas injectors 240 are shown in a second (e.g., lowered) position in FIG. 2A and in a first (e.g., raised) position in FIG. 2B. For example, the gas injectors 240 may be moved to the lowered position to dry the edge 208 of the substrate and to the raised position while wetting the substrate 204, transporting the substrate 204 to and from the chamber 200, etc.

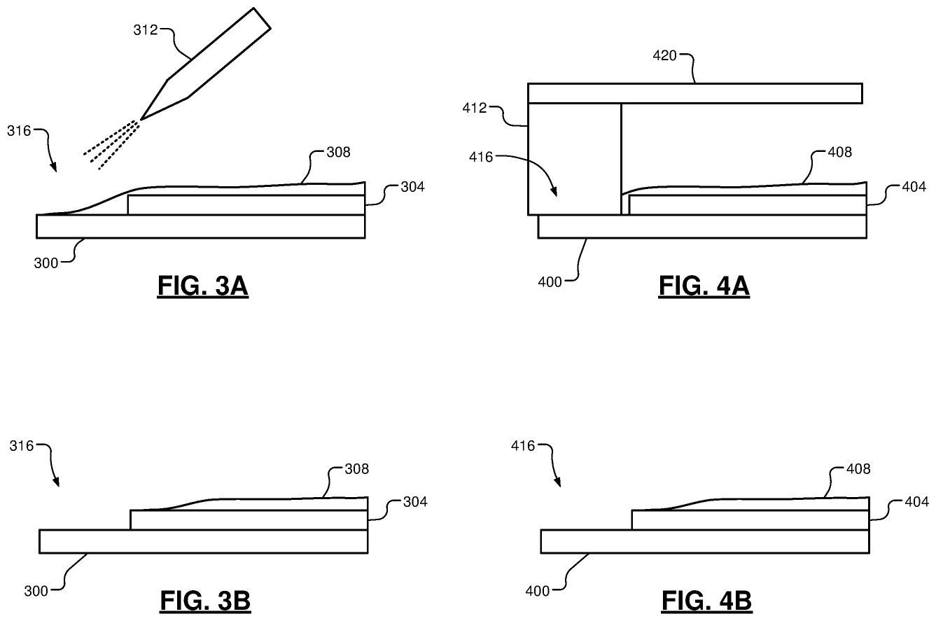

Referring now to FIGS. 3A and 3B, an example substrate 300 is shown prior to and subsequent to a predetermined drying period. As shown, a surface of the substrate 300 comprises a photoresist layer 304. In FIG. 3A, a pre-wetting liquid 308 is distributed across the substrate 300 and the photoresist layer 304. A gas injector 312 is arranged to inject a focused jet of gas to dry an edge 316 of the substrate 300 during the drying period as described above in FIGS. 2A and 2B. The substrate 300 is shown subsequent to the drying period in FIG. 3B.

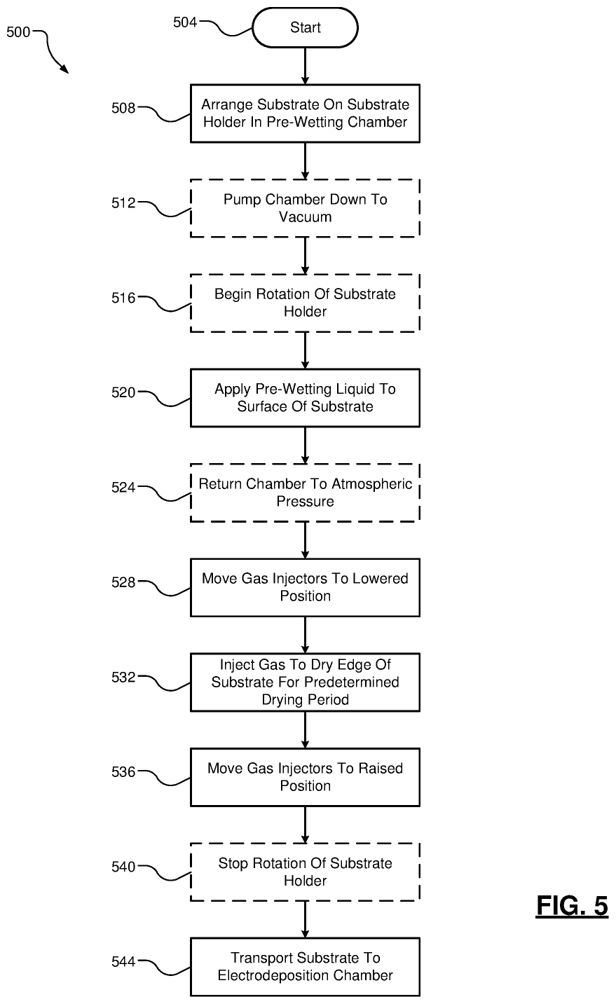

Referring now to FIGS. 4A and 4B, in another embodiment, an example substrate 400 is shown prior to and subsequent to a predetermined drying period. As shown, a surface of the substrate 400 comprises a photoresist layer 404. In FIG. 4A, a pre-wetting liquid 408 is distributed across the substrate 400 and the photoresist layer 404. Instead of using the gas injector 312 as described above in FIGS. 3A and 3B, one or more drying pads 412 are arranged to dry an edge 416 of the substrate 400 during the drying period. Only one drying pad 412 may be provided or two or more of the drying pads 412 may be arranged around a perimeter of the substrate 400 above the edge 416. In one embodiment, the drying pads 412 comprise an absorbent material (e.g., a sponge) configured to absorb the pre-wetting liquid 408 from the edge 416. In other embodiments, the drying pads 412 comprise a non-absorbent material (e.g., a non-abrasive rubber or polymer) configured to wipe or scrape the pre-wetting liquid 408 from the edge 416 when the substrate 400 is rotated.

The drying pads 412 may be lowered onto the edge 416 of the substrate 400 subsequent to the application of the pre-wetting liquid 408. For example, the drying pads 412 may be arranged on an assembly 420 that is lowered toward the substrate 400 until the drying pads 412 contact the edge 416. The substrate 400 (or, in another embodiment, the assembly 420) is rotated to allow the drying pads 412 to contact the entire edge 416. The substrate 400 is shown subsequent to the drying period in FIG. 4B.

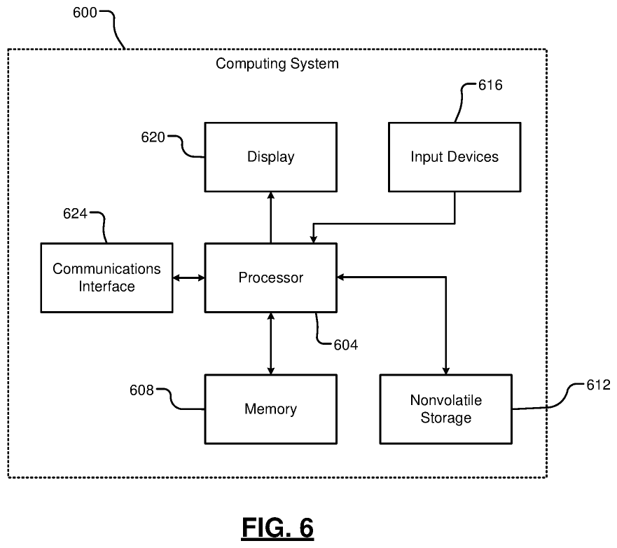

Referring now to FIG. 5, an example method 500 for drying an edge of a substrate according to the present disclosure begins at 504. For example, steps of the method 500 described below are performed in response to commands from a controller, such as the controller 236. In other words, the controller 236 is configured (e.g., structurally configured or programmed) to control components of the chamber 200 in a specific manner and/or sequence to perform the pre-wetting and edge drying processes of the method 500. At 508, the substrate is arranged on a substrate holder in a pre-wetting chamber. At 512, the chamber is optionally pumped down to vacuum. At 516, the method 500 optionally begins rotation of the substrate holder. At 520, the pre-wetting liquid is applied to the surface of the substrate. At 524, the chamber is optionally returned to atmospheric pressure.

At 528, the gas injectors are moved to a lowered position. At 532, the gas injectors are controlled to inject gas to dry the edge of the substrate for a predetermined drying period. For example, the drying period is selected to dry the edge of the substrate without removing the pre-wetting liquid from an interior region of the substrate. In one example, the drying period is less than three minutes. In another example, the drying period is less than one minute. In another example, the drying period is 1-10 seconds. At 536, the gas injectors are moved to a raised position. At 540, the rotation of the substrate holders is optionally stopped (i.e., in embodiments where the substrate holder is rotated during application of the pre-wetting liquid and/or during the drying period. At 544, the substrate is transported out of the pre-wetting chamber and into a chamber configured to perform electrodeposition.

FIG. 6 shows an example computing system 600 comprising a processor 604 and memory 608 configured to implement the controller 236 of FIGS. 2A and 2B. For example, the computing system 600 is configured to perform the method 500 of FIG. 5. In one example, the processor 604 is a special purpose processor configured to execute instructions stored in the memory 608 and/or nonvolatile storage 612. The memory 608 may be volatile memory and/or nonvolatile memory. The nonvolatile storage 612 may comprise one or more hard disk drives, semiconductor storage (e.g., solid state drives), etc.

The computing system 624 may comprise input devices such as a keyboard or keypad, touchscreen, etc. for receiving commands and other input from a user. A display 620 is configured to display information (e.g., process parameters, images, etc.). A communications interface 624 may provide wired and/or wireless communication between the computing system 600 and devices external to the computing system, such as sensors, controllers, other processing tools, etc.

The foregoing description is merely illustrative in nature and is in no way intended to limit the disclosure, its application, or uses. The broad teachings of the disclosure can be implemented in a variety of forms. Therefore, while this disclosure comprises particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, such as “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, such as a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, such as the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may comprise chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may comprise a local network or the Internet. The remote computer may comprise a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may comprise a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A chamber in a substrate processing system, the chamber comprising:
a substrate holder configured to support a substrate;
a nozzle arranged above the substrate, wherein the nozzle is configured to inject a pre-wetting liquid onto a surface of the substrate during a pre-wetting period; and
at least one gas injector arranged radially outward of the nozzle, wherein the at least one gas injector is configured to inject gas toward an edge of the substrate for a drying period subsequent to the pre-wetting period to remove the pre-wetting liquid from the edge of the substrate.

2. The chamber of claim 1, wherein the at least one gas injector is arranged to inject the gas to remove the pre-wetting liquid from the edge of the substrate without removing the pre-wetting liquid from an interior of the substrate.

3. The chamber of claim 1, wherein the at least one gas injector is arranged to inject the gas away from an interior of the substrate and radially outward toward the edge of the substrate.

4. The chamber of claim 1, wherein the at least one gas injector is arranged to inject the gas at an acute angle relative to the surface of the substrate holder.

5. The chamber of claim 1, wherein the at least one gas injector comprises two or more gas injectors that are azimuthally spaced apart.

6. The chamber of claim 1, wherein the substrate holder is configured to rotate during at least one of the pre-wetting period and the drying period.

7. The chamber of claim 1, wherein the at least one gas injector is mounted on an assembly that is configured to rotate during the drying period.

8. The chamber of claim 1, wherein the at least one gas injector is configured to move between a first position and a second position.

9. The chamber of claim 8, wherein the at least one gas injector is (i) moved to the first position during the pre-wetting period and during transport of the substrate to and from the substrate holder and (ii) moved to the second position during the drying period.

10. A system comprising the chamber of claim 1 and further comprising a controller configured to control the at least one gas injector to inject the gas during the drying period.

11. The chamber of claim 1, wherein the at least one gas injector is arranged to inject the gas radially inward from an edge of the substrate toward an interior of the substrate.

12. A method of operating a chamber configured to implement a pre-wetting process in a substrate processing system, the method comprising:
arranging a substrate on a substrate holder;
using a nozzle arranged above the substrate, injecting a pre-wetting liquid onto a surface of the substrate during a pre-wetting period; and
using at least one gas injector arranged radially outward of the nozzle, injecting gas toward an edge of the substrate for a drying period subsequent to the pre-wetting period to remove the pre-wetting liquid from the edge of the substrate.

13. The method of claim 12, wherein injecting the gas comprises injecting the gas to remove the pre-wetting liquid from the edge of the substrate without removing the pre-wetting liquid from an interior of the substrate.

14. The method of claim 12, wherein injecting the gas comprises injecting the gas away from an interior of the substrate and radially outward toward the edge of the substrate.

15. The method of claim 12, wherein injecting the gas comprises injecting the gas at an acute angle relative to the surface of the substrate holder.

16. The method of claim 12, wherein injecting the gas comprises injecting the gas using two or more gas injectors that are azimuthally spaced apart.

17. The method of claim 12, further comprising rotating the substrate holder during at least one of the pre-wetting period and the drying period.

18. The method of claim 12, further comprising rotating an assembly comprising the at least one gas injector during the drying period.

19. The method of claim 12, further comprising moving the at least one gas injector between a first position and a second position.

20. A chamber in a substrate processing system, the chamber comprising:
a substrate holder configured to support a substrate;
a nozzle arranged above the substrate, wherein the nozzle is configured to inject a pre-wetting liquid onto a surface of the substrate during a pre-wetting period; and
at least one drying pad arranged around an edge of the substrate, wherein the at least one drying pad is configured to contact the edge of the substrate for a drying period subsequent to the pre-wetting period to remove the pre-wetting liquid from the edge of the substrate.
